(19) United States
(12) Patent Application Publication
(10) Pub. No.: US 2020/0166792 A1
(43) Pub. Date: May 28, 2020

(54) ARRAY SUBSTRATE, MANUFACTURING METHOD OF THE ARRAY SUBSTRATE, AND DISPLAY DEVICE

(71) Applicant: HKC Corporation Limited, Shenzhen (CN)

(72) Inventor: Beizhou Huang, Shenzhen (CN)

(21) Appl. No.: 16/398,349

(22) Filed: Apr. 30, 2019

Related U.S. Application Data
(63) Continuation of application No. PCT/CN2018/122005, filed on Dec. 19, 2018.

(30) Foreign Application Priority Data
Nov. 26, 2018 (CN) 201811421287.X

(51) Int. Cl. G02F 1/1343; H01L 27/12

(52) U.S. Cl. CPC G02F 1/13439; G02F 1/1368; H01L 27/1248; H01L 27/1288

(57) ABSTRACT

The disclosure discloses a manufacturing method of an array substrate, which includes the following operations: providing a substrate; forming a thin film transistor on the substrate; forming a pixel electrode, and the pixel electrode is not formed on the protective layer, and the pixel electrode is directly connected with the drain metal layer.

### CROSS REFERENCE TO RELATED APPLICATIONS

The present application is a Continuation Application of PCT Application No. PCT/CN2018/122005 filed on Dec. 19, 2018, which claims the benefit of Chinese Patent Application No. 201811421287.X, filed on Sep. 26, 2018, which is incorporated herein by reference in its entirety.

### FIELD

The disclosure relates to the field of liquid crystal display technology, and in particular, relates to an array substrate, a manufacturing method of the array substrate, and a display device.

### BACKGROUND

With the continuous improvement of science and technology, more and more apparatus with display devices have participated in people's daily life and work, such as TV and mobile phones. In the field of display technology, the manufacturing of Thin Film Transistor-Liquid Crystal Display (TFT-LCD) panel TFT (Array Substrate) in the prior art has certain disadvantages, for example, it is required to form a communicating hole in the protective layer of the fourth layer to connect the ITO pixel electrode on it, but the compatibility between the ITO pixel electrode and the protective layer is not good, resulting in abnormal picture.

Currently, ITO pixel electrodes are manufactured on the protective layer of the array substrate of the liquid crystal display device, and the method of connecting the ITO pixel electrode and the drain electrode by forming a contacting hole in the protective layer may lead to abnormal picture and affect the display effect of the display device.

### SUMMARY

The main purpose of the disclosure is to provide an array substrate, a manufacturing method of the array substrate, and a display device, which aims at solving the problem that currently, an ITO pixel electrode is manufactured on a protective layer of the array substrate of the liquid crystal display device, and a method of connecting the ITO pixel electrode and the drain electrode by forming a contacting hole in the protective layer may lead to abnormal picture and affect the display effect of the display device.

In order to achieve the above object, the present disclosure provides a manufacturing method of an array substrate, which includes the following operations:

providing a substrate;

sequentially forming a gate electrode, a gate insulating layer, an active layer, a source/drain metal layer and a protective layer of the thin film transistor on the substrate;

coating a photoresist for a pixel electrodephotoresist for a pixel electrode, the pixel electrode is patternedly formed, the pixel electrode is not formed on the protective layer, and the pixel electrode directly connects the drain metal layer.

Optionally, the method further includes:

depositing a first metal layer on the substrate;

defining a pattern of the first metal layer to form a gate electrode in the first metal layer by a 1-mask etching;

depositing an insulating layer on the substrate to cover a surface of the first metal layer;

sequentially depositing a semiconductor layer, a doped silicon layer and a second metal layer, and performing a 2-mask etching to define patterns of the semiconductor layer, the doped silicon layer and the second metal layer to form a thin film transistor island structure;

performing a 3-mask etching to form a source/drain metal layer in the second metal layer and the doped silicon layer to complete the manufacturing of the thin film transistor; and

forming a protective layer on the substrate and covering the surface of the thin film transistor.

Optionally, the operation of coating the photoresist for the pixel electrode, forming the pixel electrode through exposing and developing the photoresist includes:

performing a 4-mask etching to define a pattern of the pixel electrode, and forming the pixel electrode on the gate insulating layer and not on the protective layer.

Optionally, the pixel electrode is made of indium tin oxide.

Optionally, the method further includes:

forming a common line on the substrate through an exposure process; and

forming a common electrode connected with the common line through an exposure process, the common electrode alternating with the pixel electrode in the pixel region.

In addition, in order to achieve the above object, another aspect of the present disclosure also provides an array substrate, which includes:

a substrate;

a thin film transistor, formed on the substrate, the thin film transistor including a gate electrode, a gate insulating layer, an active layer, a source/drain metal layer and a protective layer; and

a pixel electrode, formed on the gate insulating layer, not formed on the protective layer, and directly connecting the drain metal layer.

Optionally, the array substrate includes a plurality of scan lines and data lines perpendicular to the scan lines on the substrate, defining a plurality of array pixel regions.

In addition, in order to achieve the above object, another aspect of the present disclosure also provides a display device including a memory, a processor, and a computer program stored on the memory and executable by the processor, the computer program implements the operations of the method described above when being executed by the processor.

Optionally, the display device further includes:

an array substrate;

an opposite substrate defined facing to the array substrate;

a liquid crystal layer filled between the opposite substrate and the array substrate; and the array substrate including a substrate;

a thin film transistor, formed on the substrate, the thin film transistor including a gate electrode, a gate insulating layer, an active layer, a source/drain metal layer and a protective layer; and

a pixel electrode, formed on the gate insulating not formed on the protective layer, and directly connecting the drain metal layer.

Optionally, the array substrate includes a plurality of scan lines and data lines perpendicular to the scan lines on the substrate, defining a plurality of array pixel regions.

In addition, in order to achieve the above object, another aspect of the present disclosure also provides a storage medium in which an array substrate manufacturing program is stored, and when the array substrate manufacturing program is executed by a processor, the following operations are implemented:

providing a substrate;

sequentially forming a gate electrode, a gate insulating layer, an active layer, a source/drain metal layer and a protective layer of the thin film transistor on the substrate; and

coating a photoresist for a pixel electrodephotoresist for a pixel electrode, the pixel electrode is patternedly formed, the pixel electrode is not formed on the protective layer, and the pixel electrode directly connects the drain metal layer.

According to the disclosure, after finishing the manufacturing of the protective layer, directly coat the ITO pixel electrode layer, no dry etching is performed on the protective layer to generate a contacting hole in the protective layer. And the ITO pixel electrode is not formed on the protective layer and is directly contacted with the drain metal layer, thereby skipping a production process and simplifying the production process. And the ITO pixel electrode layer may not contacted with the protective layer, thereby avoiding the incompatibility problem between the protective layer and the ITO pixel electrode, improving the stability of the display device, and improving the stability and the display effect of the display picture.

### BRIEF DESCRIPTION OF THE DRAWINGS

FIG. 1 is a schematic structural diagram of a display device involving a hardware operation environment in an embodiment of the present disclosure;

FIG. 2 is a flowchart of a manufacturing method of a ay substrate an embodiment of the present disclosure;

FIG. 3 is a flowchart of forming a thin film transistor (TFT) an embodiment of the present disclosure;

FIG. 4 is a flowchart of forming an ITO pixel electrode in an embodiment of the present disclosure;

FIG. 5 is a schematic structural diagram of an array substrate in an embodiment of the present disclosure;

FIG. 6 is a schematic structural diagram of a display device in an embodiment of the present disclosure.

The realization, functional features and advantages of the purpose of the present disclosure will be further described with reference to the accompanying drawings in conjunction with the embodiments.

### DETAILED DESCRIPTION OF THE EMBODIMENTS

It should be understood that the specific embodiments described herein are only for the purpose of explaining the present disclosure and are not intended to limit the present disclosure.

The main solution of the embodiments of the disclosure is to provide a substrate; sequentially forming a gate electrode, a gate insulating layer, an active layer, a source/drain metal layer and a protective layer of the thin film transistor on the substrate; after the formation of the protective layer, coating a photoresist for a pixel electrode, forming the pixel electrode through exposing and developing the photoresist, the pixel electrode being formed not on the protective layer, and the pixel electrode directly connecting the drain metal layer.

Since currently the ITO pixel electrode is manufactured on the protective layer on the array substrate of the liquid crystal display device, the method of connecting the ITO pixel electrode and the drain electrode by forming a contacting hole in the protective layer may lead to abnormal picture and affect the display effect of the display device. The disclosure provides a solution that after finishing the manufacturing of the protective layer, directly coat the ITO pixel electrode layer, no dry etching is performed to generate a contacting hole in the protective layer. The ITO pixel electrode is not formed on the protective layer and is directly contacted with the drain metal layer, thereby skipping a production process and simplifying the production process. and the ITO pixel electrode layer may not contacted with the protective layer, thereby avoiding the incompatibility problem between the protective layer and the ITO pixel electrode, improving the stability of the display device, and improving the stability and the display effect of the display picture.

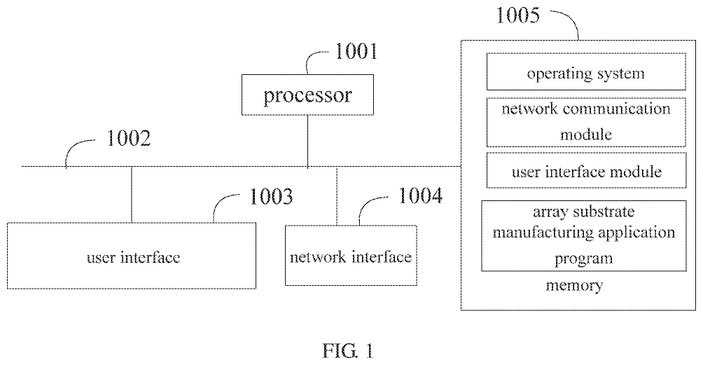

As shown in FIG. 1. FIG. 1 is a schematic structural diagram of a display device involving a hardware operation environment in an embodiment of the present disclosure.

As shown in FIG. 1, the display device may include a processor 1001, such as a CPU, a network interface 1004, a user interface 1003, a memory 1005, and a communication bus 1002. And, the communication bus 1002 is configured to enable connecting communication between these components. The user interface 1003 may include a display, an input unit such as a keyboard, and the optional user interface 1003 may also include a standard wired interface and a wireless interface. The network interface 1004 may optionally include a standard wired interface, a wireless interface (such as a WI-FI interface). The memory 1005 may be a SRAM memory or a non-volatile memory, such as a disk memory. The memory 1005 may optionally be a memory device independent from the aforementioned processor 1001.

Optionally, the display device may also include a camera, a radio frequency (RF) circuit, a sensor, an audio circuit, a WiFi module, and the like.

It may be understood by those skilled in the art that the terminal structure shown in FIG. 1 does not constitute a definition of a display device, and may include more or fewer components than that are shown in the FIG. 1, or may combine some components, or may be different arrangements of the components.

As shown in FIG. 1, a memory 1005 as a storage medium may include an operating system, a network communication module, a user interface module, and an array substrate manufacturing application program.

In the display device shown in FIG. 1, the network interface 1004 is mainly configured to connect with the background server and communicate data with the background server. The user interface 1003 is mainly configured to connect the client (user) and communicate data with the client. and the processor 1001 may be configured to enable the array substrate manufacturing application stored in the memory 1005 and execute the following operations:

providing a substrate;

sequentially forming a gate electrode, a gate insulating layer, an active layer, a source/drain metal layer and a protective layer of the thin film transistor on the substrate;

coating a photoresist for a pixel electrode, and the pixel electrode is patternedly formed, the pixel electrode is not formed on the protective layer, and the pixel electrode directly connects the drain metal layer.

Further, the processor 1001 may be configured to enable the array substrate manufacturing application stored in the memory 1005 and execute the following operations:

depositing a first metal layer on the substrate;

defining a pattern of the first metal layer to form a gate electrode in the first metal layer by a 1-mask etching;

depositing an insulating layer on the substrate to cover a surface of the first metal layer;

sequentially depositing a semiconductor layer, a doped silicon layer and a second metal layer, and performing a 2-mask etching to define patterns of the semiconductor layer, the doped silicon layer and the second metal layer to form a thin film transistor island structure;

performing a 3-mask etching to form a source/drain metal layer in the second metal layer and the doped silicon layer to complete the manufacturing of the thin film transistor; and

forming a protective layer on the substrate and covering the surface of the thin film transistor.

Further, the processor 1001 may be configured to enable the array substrate manufacturing application stored in the memory 1005 and execute the following operations:

performing a 4-mask etching to define a pattern of the pixel electrode, and forming the pixel electrode on the gate insulating layer and not on the protective layer.

Further, the processor 1001 may be configured to enable the array substrate manufacturing application stored in the memory 1005 and execute the following operations: the pixel electrode is composed of indium tin oxide.

Further, the processor 1001 may be configured to enable the array substrate manufacturing application stored in the memory 1005 and execute the following operations:

forming a common line on the substrate through an exposure process; and

forming a common electrode connected with the common line through an exposure process, the common electrode alternating with the pixel electrode in the pixel region.

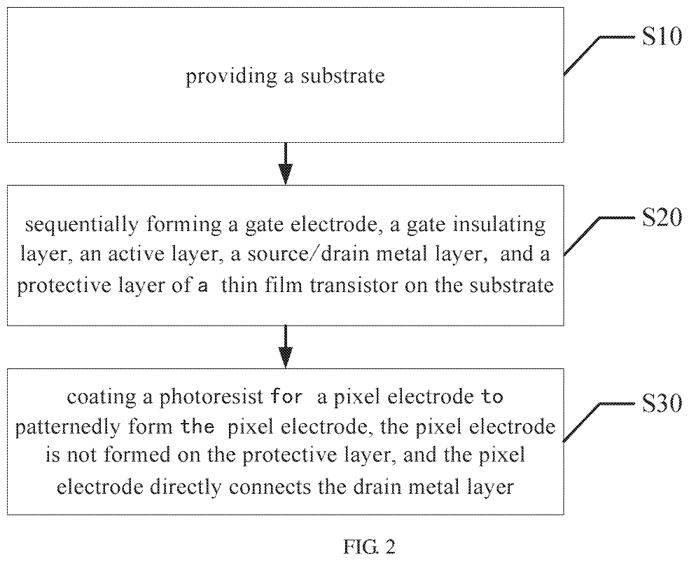

Referring to FIG. 2, an embodiment of the present disclosure provides a manufacturing method of an array substrate, which includes:

Operation S10, providing a substrate;

In this embodiment, a substrate is provided, the substrate is an array substrate, and the substrate is made of glass or other materials suitable for display, such as silicon substrates.

Operation S20: sequentially forming a gate electrode, a gate insulating layer, an active layer, a source/drain metal layer and a protective layer of the thin film transistor on the substrate;

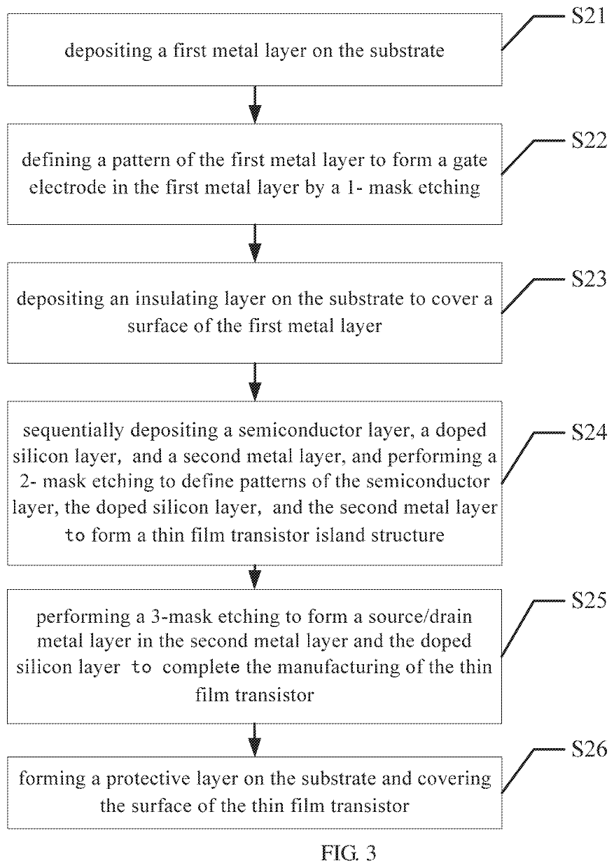

a gate electrode, a gate insulating layer, an active layer, a source/drain metal layer, and a passivation layer of the thin film transistor (TFT) are sequentially formed on the substrate. Referring to FIG. 3, the process of forming the TFT includes:

Operation S21, depositing a first metal layer on the substrate;

In operation S22, defining a pattern of the first metal layer to form a gate electrode in the first metal layer by a 1-mask etching;

Operation S23, depositing an insulating layer on the substrate to cover a surface of the first metal layer;

Operation S24, sequentially depositing a semiconductor layer, a doped silicon layer and a second metal layer, and performing a 2-mask etching to define patterns of the semiconductor layer, the doped silicon layer and the second metal layer to form a thin film transistor island structure;

Operation S25, performing a 3-mask etching to form a source/drain metal layer in the second metal layer and the doped silicon layer to complete the manufacturing of the thin film transistor; and

Operation S26, forming a protective layer on the substrate and covering the surface of the thin film transistor.

The TFT is:

A. metal 1 process, the first metal layer;

Metal 1 coating, photoresist coating/exposure/development, M1 wet etching, photoresist removal;

B. GIN process, insulating layer;

GIN Coating by Chemical Vapor Deposition (CVD), Photoresist Coating/Exposure/Development, GIN Layer Etching, Photoresist Removal;

C. Metal 2 Process, the second metal layer;

Metal 2 coating, photoresist coating/exposure/development, M2 wet etching, N+etching, photoresist removal;

D. Passivation Process, protective layer manufacturing process;

CVD passivation coating, photoresist coating/exposure/development, passivation etching, photoresist removal.

However, after the formation of the protective layer, no dry etching is performed and no contacting hole is formed in the protective layer until the etching is finished, forming the protective layer pattern.

First, a first metal layer is deposited on the full surface of the substrate, then a 1-mask etching is performed to form a gate electrode and a scanning line on the substrate. And the gate electrode and the scanning line are connected. After finishing the 1-mask etching, an insulating layer, a semiconductor layer, a doped silicon layer and a second metal layer are deposited on the full substrate. The semiconductor layer is made of polysilicon or amorphous silicon and is defined according to the manufacturing process and display requirements. Next, a 2-musk etching is performed to define a semiconductor layer, a doped silicon layer and the second metal layer pattern to form a thin film transistor island structure. Performing a 3-mask etching to form a signal line, a source and a drain metal layer on the second metal layer and the doped silicon layer, finishing the manufacturing of the thin film transistor (TFT). After the 3-mask etching is finished, a protective layer is formed on the substrate and covers the surfaces of the TFT thin film transistor and the signal line. However, dry etching of the protective layer is not performed here, and no source electrode contacting hole, drain contacting hole and signal line contacting hole are formed.

Operation S30: coating a photoresist for a pixel electrode, and the pixel electrode is patternedly formed, the pixel electrode is not formed on the protective layer, and the pixel electrode directly connects the drain metal layer.

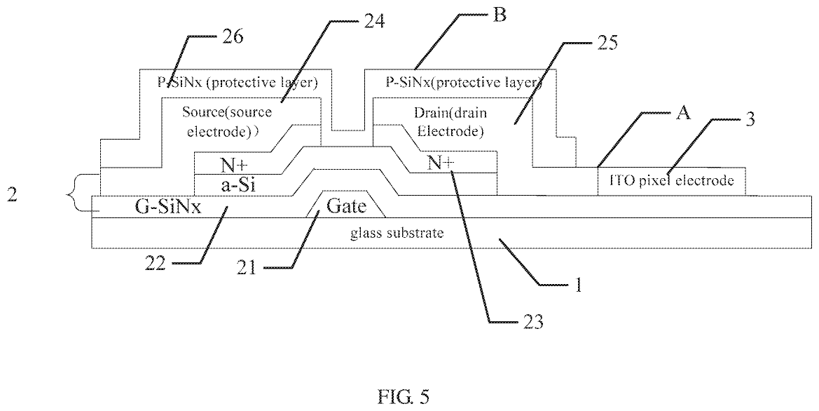

After the formation of the protective layer, directly coat the photoresist of the ITO pixel electrode, no dry etching is performed on the protective layer to form a contacting hole, form the pixel electrode through exposing and developing the photoresist, and the pixel electrode is formed not on the protective layer, and the pixel electrode directly connecting the drain metal layer. Here, the process of making a contacting hole by dry etching of a protective layer is skipped, and the ITO pixel electrode is directly connected with the Drain electrode. Referring to FIG. 5, after the ITO pixel electrode is coated, the ITO pixel electrode is directly attached to the Drain electrode at the A position in a patterned manner without forming the contacting hole in the protective layer by etching as in the conventional process, and the ITO pixel electrode is filled into the contacting hole to make them contact. At the B position, in the conventional process, the ITO pixel electrode is covered on the protective layer, excluding this embodiment.

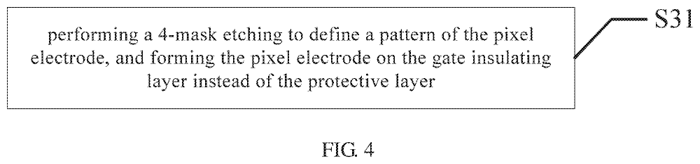

Referring to FIG. 4, ITO pixel electrodes are manufactured in the following manner:

Operation S31, performing a 4-mask etching to define a pattern of the pixel electrode, and forming the pixel electrode on the gate insulating layer and not on the protective layer. After forming the protective layer, ITO photoresist is deposited on the full substrate, the ITO pixel electrode is formed on the gate layer by a 4-mask etching (development), ITO wet etching, photoresist removal, and ITO OVEN (baking), and is not formed on the protective layer. ITO pixel electrode directly connects the drain metal layer, rather than uses a contacting hole to realize the connection.

In order to improve the conductivity of the pixel electrode, the material of the pixel electrode is indium tin oxide (ITO), and in other embodiments of the present disclosure, the material of the pixel electrode may also be other conductive materials.

According to the embodiment, after finishing the production of protective layer, directly coat the ITO pixel electrode layer, and no dry etching is performed to generate a contacting hole in the protective layer, and the ITO pixel electrode is not formed on the protective layer and is directly contacted with the drain metal layer, thereby skipping a production process and simplifying the production process. and the ITO pixel electrode layer may not contacted with the protective layer, thereby avoiding the incompatibility problem between the protective layer and the ITO pixel electrode, improving the stability of the display device, and improving the stability and the display effect of the display picture.

In an embodiment, an array substrate is provided, referring to FIG. 5, the array substrate includes:

a substrate 1,

a thin film transistor 2, formed on the substrate, the thin film transistor including a gate 21, a gate insulating layer 22, an active layer 23, a source 24/drain metal layer 25 and a protective layer 26;

a pixel electrode 3, formed on the gate insulating layer 22, not formed on the protective layer 26, and directly connecting the drain metal layer 22.

The TET is manufactured on a transparent substrate 1, the substrate is defined with at least one thin film transistor 2, a plurality of scan lines and a plurality of signal lines vertically staggered with the scan lines. The thin film transistor 2 includes a gate 21, a gate insulating layer 22, an active layer 23, a source 24/drain metal layer 25 and a protective layer 26. A plurality of scan lines and the data lines perpendicular to the scan lines are located on the substrate to define a plurality of array pixel areas.

Each thin film transistor 2 is configured to drive a pixel electrode made of ITO, the pixel electrode is defined above the staggered areas which are formed by the signal lines and the scan lines, and the pixel electrode is formed on the gate layer, not on the protective layer, and is in direct contact with the drain metal layer.

According to the array substrate of the embodiment, after finishing the production of the protective layer, directly coat the ITO pixel electrode layer, and no dry etching is performed to generate a contacting hole in the protective layer, and the ITO pixel electrode is not formed on the protective layer and is directly contacted with the drain metal layer, thereby skipping a production process and simplifying the production process. and the ITO pixel electrode layer may not contacted with the protective layer, thereby avoiding the incompatibility problem between the protective layer and the ITO pixel electrode, improving the stability of the display device, and improving the stability and the display effect of the display picture.

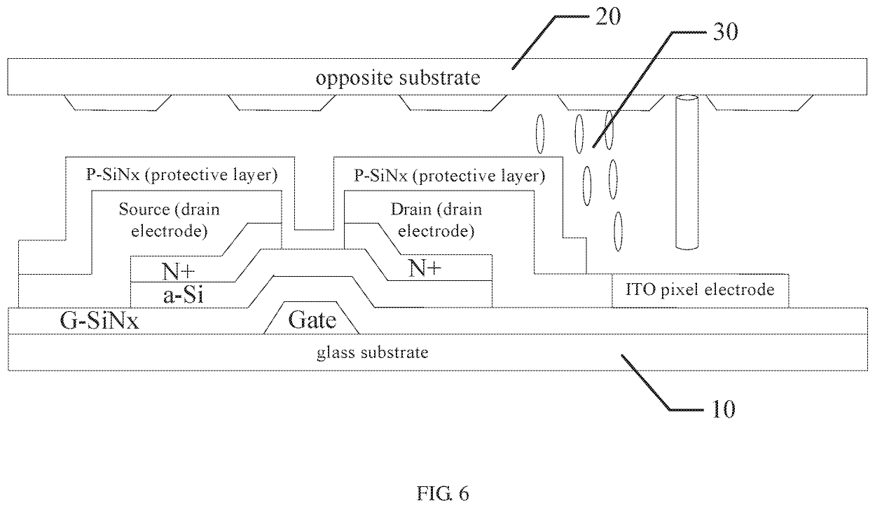

In an embodiment, a display device is provided. referring to FIG. 6, the display device includes:

the array substrate 10 as described above;

an opposite substrate 20 defined facing to the array substrate 10;

a liquid crystal layer 30, filled between the opposite substrate 20 and the array substrate 10.

The TFT is manufactured on a transparent substrate 1, the substrate is defined with at least one thin film transistor, a plurality of scan lines and a plurality of signal lines vertically staggered with the scan lines. The thin film transistor includes a gate, a gate insulating layer, an active layer, a source/drain metal layer and a protective layer. A plurality of scan lines and the data lines perpendicular to the scan lines are located on the substrate to define a plurality of array pixel areas.

Each thin film transistor is configured to drive a pixel electrode made of ITO, the pixel electrode is defined above the staggered areas which are formed by the signal lines and the scan lines, and the pixel electrode is formed on the gate layer, not on the protective layer, and is in direct contact with the drain metal layer.

The opposite substrate includes a color filter, and the color filter is as follows: providing a substrate, depositing and etching a black matrix on the substrate, and forming a color resist on the substrate between the black matrices, the color resist includes but is not limited to a red resist, a green resist and a blue resist; forming a common electrode covering the color resist and the black matrix, forming a spacer on the common electrode, and forming a pad at a position of the TFT corresponding to the spacer.

In order to save the process, the pad is a single layer or multiple layers in the materials including the formed gate insulating layer, active layer or passivation layer. That is, the pad and a single layer or multiple layers in the formed gate insulating layer, active layer or passivation layer material are formed synchronously. The liquid crystal is filled between the array substrate and the opposite substrate, and under the control of the voltage of the array substrate, the liquid crystal deflects through the opposite substrate to form the required color for display and output the required picture according to the input signal.

According to the display device of the embodiment, after finishing the production of the protective layer, directly coat the ITO pixel electrode layer, and no dry etching is performed to generate a contacting hole in the protective layer, and the ITO pixel electrode is not formed on the protective layer and is directly contacted with the drain metal layer, thereby skipping a production process and simplifying the production process. and the ITO pixel electrode layer may not contacted with the protective layer, thereby avoiding the incompatibility problem between the protective layer and the ITO pixel electrode, improving the stability of the display device, and improving the stability and the display effect of the display picture.

In addition, the embodiment of the disclosure also provides a display device, which includes a display panel and a processor connected with the display panel. The processor is loaded with a manufacturing control device of the array substrate, the display panel completes the manufacturing control of the array substrate under the control of the processor, and the manufacturing method of the array substrate stored in the processor is completed by the array substrate manufacturing method n the above-mentioned embodiments, and the array substrate manufacturing method is loaded in the array substrate manufacturing device for the processor to enable and start the process control for completing the manufacturing of the array substrate, thereby improving the stability and effect of the display screen of the display device. The display device may be a mobile or fixed display device such as a television, a mobile phone, a pad, a display machine, etc. According to the display device of the embodiment, after finishing the production of the protective layer, directly coat the ITO pixel electrode layer, and no dry etching is performed to generate a contacting hole in the protective layer, and the ITO pixel electrode is not formed on the protective layer and is directly contacted with the drain metal layer, thereby skipping a production process and simplifying the production process. and the ITO pixel electrode layer may not contacted with the protective layer, thereby avoiding the incompatibility problem between the protective layer and the ITO pixel electrode, improving the stability of the display device, and improving the stability and the display effect of the display picture.

In addition, the embodiment of the disclosure also provides a storage medium, a storage medium, on which an array substrate manufacturing program is stored, and when the array substrate manufacturing program is executed by the processor, the array substrate manufacturing method described in the embodiments above is realized.

It should be noted that in this document, the terms “comprise”, “include” or any other variation thereof, are intended to cover a non-exclusive inclusion, such that a process, method, article, or system that includes a series of elements includes not only those elements but also other elements not expressly listed, or elements inherent to such process, method, article, or system. Without further limitation, the element defined by the statement “including one . . . ” does not exclude the existence of another identical element in the process, method, article or system that includes the element.

The above-mentioned serial numbers of the embodiments of the present disclosure are for the purpose of description only and do not represent the advantages and disadvantages of the embodiments.

From the description of the above embodiments, it is clear to those skilled in the art that the method of the above embodiments may be implemented by means of software and necessary general-purpose hardware platform, although it may also be implemented by hardware, but in many cases the former is a preferred embodiment. Substrated on such understanding, the technical schemes of the present disclosure, in essence, or the part contributing to the prior art, may be embodied in the form of a software product. The software product is stored in a storage medium (such as ROM/RAM, magnetic disk, optical disk) as described above, including several instructions for enabling a terminal device (which may be a mobile phone, computer, server, air conditioner, or network device, etc.) to perform the methods described in various embodiments of the present disclosure.

The above is only an alternative embodiment of the present disclosure and is not intended to limit the patent scope of the present disclosure. Any equivalent structure or equivalent process transformation made by using the contents of the specification and drawings of the present disclosure, or directly or indirectly applied in other related technical fields, is similarly included in the patent protection scope of the present disclosure.

What is claimed is:

1. A manufacturing method of an array substrate, wherein the manufacturing method comprises:
providing a substrate;
sequentially forming a gate electrode, a gate insulating layer, an active layer, a source/drain metal layer, and a protective layer of a thin film transistor on the substrate; and
coating a photoresist for a pixel electrode to patternedly form the pixel electrode, the pixel electrode is not formed on the protective layer, and the pixel electrode directly connects the drain metal layer.

2. The manufacturing method according to claim 1, wherein the manufacturing method further comprises:
depositing a first metal layer on the substrate;
defining a pattern of the first metal layer to form a gate electrode in the first metal layer by a 1-mask etching;
depositing an insulating layer on the substrate to cover a surface of the first metal layer;
sequentially depositing a semiconductor layer, a doped silicon layer, and a second metal layer, and performing a 2-mask etching to define patterns of the semiconductor layer, the doped silicon layer, and the second metal layer to form a thin film transistor island structure;
performing a 3-mask etching to form a source/drain metal layer in the second metal layer and the doped silicon layer to complete the manufacturing of the thin film transistor; and
forming a protective layer on the substrate and covering the surface of the thin film transistor.

3. The manufacturing method according to claim 2, wherein the manufacturing method further comprises:
forming a common line on the substrate through an exposure process; and
forming a common electrode connected with the common line through an exposure process, the common electrode alternating with the pixel electrode in the pixel region.

4. The manufacturing method according to claim 2, wherein the pixel electrode is made of indium tin oxide.

5. The manufacturing method according to claim 2, wherein the operation of coating a photoresist for a pixel electrode, forming the pixel electrode through exposing and developing the photoresist comprises:
performing a 4-mask etching to define a pattern of the pixel electrode, and forming the pixel electrode on the gate insulating layer instead of the protective layer.

6. The manufacturing method according to claim 5, wherein the manufacturing method further comprises:
forming a common line on the substrate through an exposure process; and
forming a common electrode connected with the common line through an exposure process, the common electrode alternating with the pixel electrode in the pixel region.

7. The manufacturing method according to claim 1, wherein the pixel electrode is made of indium in oxide.

8. The manufacturing met od according to claim 1, wherein the manufacturing method further comprises:
forming a common line on the substrate through an exposure process; and
forming a common electrode connected with the common line through an exposure process, the common electrode alternating with the pixel electrode in the pixel region.

9. An array substrate, wherein the array substrate comprises:
a substrate;
a thin film transistor, formed on the substrate, the thin film transistor comprising a gate electrode, a gate insulating layer, an active layer, a source/drain metal layer, and a protective layer; and
a pixel electrode, formed on the gate insulating layer instead of the protective layer, and directly connecting the drain metal layer.

10. The array substrate according to claim 9, wherein the array substrate comprises a plurality of scan lines and data lines perpendicular to the scan lines on the substrate, defining a plurality of array pixel regions.

11. The array substrate according to claim 9, wherein the pixel electrode is made of indium tin oxide.

12. A display device, wherein the display device comprises a memory, a processor, and a computer program stored in the memory and executable by the processor, when being executed by the processor, the computer program implements the following operations:
providing a substrate;
sequentially forming a gate electrode, a gate insulating layer, an active layer, a source/drain metal layer and a protective layer of the thin film transistor on the substrate; and
coating a photoresist for a pixel electrode photoresist for a pixel electrode to patternedly form the pixel electrode, the pixel electrode is not formed on the protective layer, and the pixel electrode directly connects the drain metal layer.

13. The display device according to claim 12, wherein when being executed by the processor, the computer program implements the following operations:
depositing a first metal layer on the substrate;
defining a pattern of the first metal layer to form a gate electrode in the first metal layer by a 1-mask etching;
depositing an insulating layer on the substrate to cover a surface of the first metal layer;
sequentially depositing a semiconductor layer, a doped silicon layer and a second metal layer, and performing a 2-mask etching to define patterns of the semiconductor layer, the doped silicon layer and the second metal layer to form a thin film transistor island structure;
performing a 3-mask etching to form a source/drain metal layer in the second metal layer and the doped silicon layer to complete the manufacturing of the thin film transistor; and
forming a protective layer on the substrate and covering the surface of the thin film transistor.

14. The display device according to claim 12, wherein when being executed by the processor, the computer program implements the following operations:
performing a 4-mask etching to define a pattern of the pixel electrode, and forming the pixel electrode on the gate insulating layer instead of the protective layer.

15. The display device according to claim 12, wherein the pixel electrode is made of indium tin oxide.

16. The display device according to claim 12, wherein when being executed by the processor, the computer program implements the following operations:
forming a common line on the substrate through an exposure process; and
forming a common electrode connected with the common line through an exposure process, the common electrode alternating with the pixel electrode in the pixel region.

17. The display device of claim 12, wherein the display device further comprises:
an array substrate;
an opposite substrate, defined facing to the array substrate; and
a liquid crystal layer, filled between the opposite substrate and the array substrate, wherein the array substrate comprises: a substrate;
a thin film transistor, formed on the substrate, the thin film transistor comprising a gate electrode, a gate insulating layer, an active layer, a source/drain metal layer, and a protective layer; and
a pixel electrode, formed on the gate insulating layer instead of the protective layer, and directly connecting the drain metal layer.

18. The display device according to claim 12, wherein the array substrate comprises a plurality of scan lines and data lines perpendicular to the scan lines on the substrate, defining a plurality of array pixel regions.

19. The display device according to claim 12, in the operation of manufacturing the opposite substrate comprises:
providing a substrate, depositing and etching a black matrix on the substrate, and forming a color resist on the substrate among the black matrix, wherein the color resist comprises but is not limited to a red resist, a green resist, and a blue resist;
forming a common electrode covering the color resist and the black matrix, forming a spacer on the common electrode, and forming a pad at a position of the TFT corresponding to the spacer.

20. The display device of claim 19, wherein the pad is a single layer or multiple layers comprising the formed gate insulating layer, active layer, or passivation layer material.
